(19) United States
(12) Patent Application Publication
(10) Pub. No.: US 2026/0118392 A1
(43) Pub. Date: Apr. 30, 2026

(54) POWER-SUPPLY CONTROL APPARATUS AND OVERCURRENT DETECTION METHOD

(71) Applicant: Alps Alpine Co., Ltd., Tokyo (JP)

(72) Inventors: Takahiro TAOKA, Miyagi-ken (JP); Akira MIYAJI, Miyagi-ken (JP); Akira FUKUI, Miyagi-ken (JP)

(21) Appl. No.: 19/431,388

(22) Filed: Dec. 23, 2025

Related U.S. Application Data
(63) Continuation of application No. PCT/JP2024/006090, filed on Feb. 20, 2024.

(30) Foreign Application Priority Data
Jul. 5, 2023 (JP) 2023-110421

(51) Int. Cl. G01R 19/165; G01R 15/20; G01R 19/00

(52) U.S. Cl. CPC G01R 19/16585; G01R 15/205; G01R 19/0092

(57) ABSTRACT

In a power-supply control apparatus according to the present invention including a current sensor including a magnetic sensor that detects, using a magnetoresistive element, magnetism generated when a current to be measured flows through a bus bar, the current sensor being capable of measuring the current to be measured; and a determination unit that determines whether an overcurrent has flowed through the bus bar, the determination unit measures a current increase time and a current decrease time, obtains a current increase/decrease time difference that is a difference between the current increase time and the current decrease time, and determines whether the overcurrent has flowed through the bus bar based on the current increase/decrease time difference.

### CLAIM OF PRIORITY

This application is a Continuation of International Application No. PCT/JP2024/006090 filed on Feb. 20, 2024, which claims benefit of Japanese Patent Application No. 2023-110421 filed on Jul. 5, 2023. The entire contents of each application noted above are hereby incorporated by reference.

### BACKGROUND OF THE INVENTION

### 1. Field of the Invention

The present invention relates to a power-supply control apparatus that controls a vehicle power-supply system or the like by measuring a current to be measured flowing through various devices, and to an overcurrent detection method.

### 2. Description of the Related Art

In recent years, power-supply control apparatuses including a current sensor that measures a current to be measured flowing through various devices have been used to control power-supply systems of vehicles equipped with various devices. For example, Japanese Unexamined Patent Application Publication No. 2018-57244 describes a power-supply control apparatus including a switch control unit that opens a switch provided in an electrical path based on a determination result of an overcurrent determination unit, in order to ensure appropriate handling when an overcurrent occurs. The power-supply control apparatus described in this literature determines whether an overcurrent has occurred by measuring a current flowing through an inverter using a current sensor.

The power-supply control apparatus described in Japanese Unexamined Patent Application Publication No. 2018-57244 needs to widen the current measurement range of its current sensor to a range in which an overcurrent can be measured. However, widening the measurable range of the current sensor results in a problem in that the measurement accuracy for a normal current decreases.

Furthermore, because the power-supply control apparatus described in the literature measures an overcurrent that occurs while the current sensor is in operation, it cannot detect an overcurrent caused by, for example, a short circuit that occurs during maintenance of a vehicle when the power-supply control apparatus is not operating. Accordingly, when the power-supply control apparatus is in a non-operating state before being started, it is impossible to detect that an overcurrent has been applied to the power-supply control apparatus or to various devices such as an inverter. Furthermore, even when the current sensor is operating, there is a possibility that an overcurrent that occurs instantaneously cannot be detected, depending on the sampling timing.

### SUMMARY OF THE INVENTION

The present invention provides a power-supply control apparatus that can detect an overcurrent that occurs when the current sensor is not operating, in addition to when the current sensor is operating, without reducing the accuracy of the current sensor in measuring a normal current.

The present invention has the following configuration as a means for solving the above issues. A power-supply control apparatus includes a current sensor including a magnetic sensor that detects, using a magnetoresistive element, magnetism generated when a current to be measured flows through a bus bar, the current sensor being capable of measuring the current to be measured; and a determination unit that determines whether an overcurrent has flowed through the bus bar, wherein the determination unit measures a current increase time, the current increase time being a time required for an output voltage of the current sensor to rise from 0 to a maximum value, and a current decrease time, the current decrease time being a time required for the output voltage of the current sensor to fall from the maximum value to 0, obtains a current increase/decrease time difference that is a difference between the current increase time and the current decrease time, and determines whether the overcurrent has flowed through the bus bar based on the current increase/decrease time difference.

When an overcurrent exceeding the rated current of the bus bar flows through the bus bar, strong magnetism is generated from the bus bar and is applied to the magnetoresistive element. When the magnetism is equal to or greater than a predetermined strength, the state of the magnetoresistive element changes, and hysteresis occurs in which the changed state is maintained even after the magnetism is removed. The hysteresis of the magnetic sensor can be measured as a current increase/decrease time difference between a current increase time and a current decrease time. For this reason, by obtaining the current increase/decrease time difference, it is possible to detect whether strong magnetism has been generated by an overcurrent that has flowed through the bus bar. Accordingly, it is possible to determine whether an overcurrent has flowed through the bus bar based on the current increase/decrease time difference.

When the determination unit determines that the overcurrent has flowed through the bus bar, the determination unit may output a warning to the outside. By outputting a warning to the outside when an overcurrent has flowed through the bus bar, it is possible to notify a host system or the like that a problem may have occurred in the power-supply control apparatus or in a device to be controlled due to the overcurrent. This makes it possible to take countermeasures such as inspection or repair against problems that may occur due to the overcurrent.

A storage unit that stores a threshold of the current increase/decrease time difference may be provided, the threshold serving as a reference for the determination unit to determine whether a current that has flowed through the bus bar is the overcurrent, wherein when the obtained current increase/decrease time difference has exceeded the threshold, the determination unit may determine that the overcurrent has flowed through the bus bar.

By storing, as a threshold, a current increase/decrease time difference corresponding to hysteresis that occurs when an overcurrent has flowed through the bus bar, it is possible to determine that an overcurrent has flowed when the obtained current increase/decrease time difference exceeds the threshold.

A storage unit that stores a variation-amount threshold of the current increase/decrease time difference may be provided, the variation-amount threshold serving as a reference for the determination unit to determine whether a current that has flowed through the bus bar is the overcurrent, and an initial value of the current increase/decrease time difference, wherein the determination unit may obtain a variation amount of the current increase/decrease time difference, the variation amount being a difference between the obtained current increase/decrease time difference and the initial value of the current increase/decrease time difference, and may determine that the overcurrent has flowed through the bus bar when the obtained variation amount exceeds the variation-amount threshold.

Since the current increase/decrease time difference that occurs due to an overcurrent through the bus bar may vary depending on individual variations of the magnetic sensor, a variation amount with respect to the initial value of the current increase/decrease time difference is obtained and used for overcurrent determination. This makes it possible to eliminate the influence of individual variations, thereby improving the accuracy of overcurrent determination.

An overcurrent detection method includes: measuring a current to be measured that flows through a bus bar using a current sensor including a magnetic sensor that detects, using a magnetoresistive element, magnetism generated when the current to be measured flows through a bus bar, the current sensor being capable of measuring the current to be measured; measuring a current increase time, the current increase time being a time required for an output voltage of the current sensor to rise from 0 to a maximum value, and a current decrease time, the current decrease time being a time required for the output voltage of the current sensor to fall from the maximum value to 0; obtaining a current increase/decrease time difference that is a difference between the current increase time and the current decrease time; and determining whether an overcurrent has flowed through the bus bar based on the current increase/decrease time difference.

When the obtained current increase/decrease time difference exceeds a threshold, it may be determined that the overcurrent has flowed through the bus bar.

A variation amount of the current increase/decrease time difference may be obtained, the variation amount being a difference between the obtained current increase/decrease time difference and the initial value of the current increase/decrease time difference, and it may be determined that the overcurrent has flowed through the bus bar when the obtained variation amount exceeds the variation-amount threshold.

By measuring a current increase time and a current decrease time based on a measurement result of the current to be measured, and obtaining a current increase/decrease time difference, which is a difference between these times, it is possible to determine the influence on the magnetic sensor of magnetism generated when the current to be measured flows through the bus bar. This makes it possible to determine whether an overcurrent has flowed through the bus bar by using the current increase/decrease time difference.

The current increase/decrease time difference at the output voltage of the current sensor immediately after startup or the variation amount may be obtained, and when the current increase/decrease time difference exceeds the threshold, or when the variation amount exceeds the variation-amount threshold, a warning indicating a high likelihood that the overcurrent flowed while the current sensor was stopped may be output.

When it is determined immediately after the startup of the current sensor that an overcurrent has flowed through the bus bar, it can be said that there is a high likelihood that the overcurrent flowed while the current sensor was stopped. Accordingly, a warning indicating a high likelihood that the overcurrent flowed while the current sensor was stopped is output to the outside. This warning can alert the operator to the possibility that an overcurrent may have flowed while the current sensor was stopped, for example, due to a short circuit caused by an operational error during maintenance of the power-supply control apparatus. This therefore makes it easier for the operator to select more appropriate countermeasures.

### BRIEF DESCRIPTION OF THE DRAWINGS

FIG. 1 is a functional block diagram illustrating a configuration of a power-supply control apparatus according to an embodiment of the present invention;

FIG. 2 is a schematic cross-sectional view of a configuration of a magnetic sensor;

FIG. 3A is a graph showing a relationship between a primary current detected by a current sensor and an output voltage of the current sensor;

FIG. 3B is a graph showing changes over time in the voltage output from the current sensor, and illustrating differences depending on whether hysteresis has occurred in the magnetic sensor;

FIG. 4 is a graph showing hysteresis that occurs in the magnetic sensor when strong magnetism is applied;

FIG. 5A is a graph showing the relationship between a primary current detected by the current sensor and an output voltage of the current sensor, and illustrating differences depending on whether an offset has occurred in the magnetic sensor;

FIG. 5B is a graph showing changes over time in the voltage output from the current sensor, and illustrating differences depending on whether an offset has occurred in the magnetic sensor;

FIG. 6 is a flowchart of an overcurrent detection method according to an embodiment;

FIG. 7 is a flowchart of an overcurrent detection method according to Modification 1; and

FIG. 8 is a flowchart of an overcurrent detection method according to Modification 2.

### DESCRIPTION OF THE PREFERRED EMBODIMENTS

Embodiments of the present invention will be described hereinbelow with reference to the accompanying drawings.

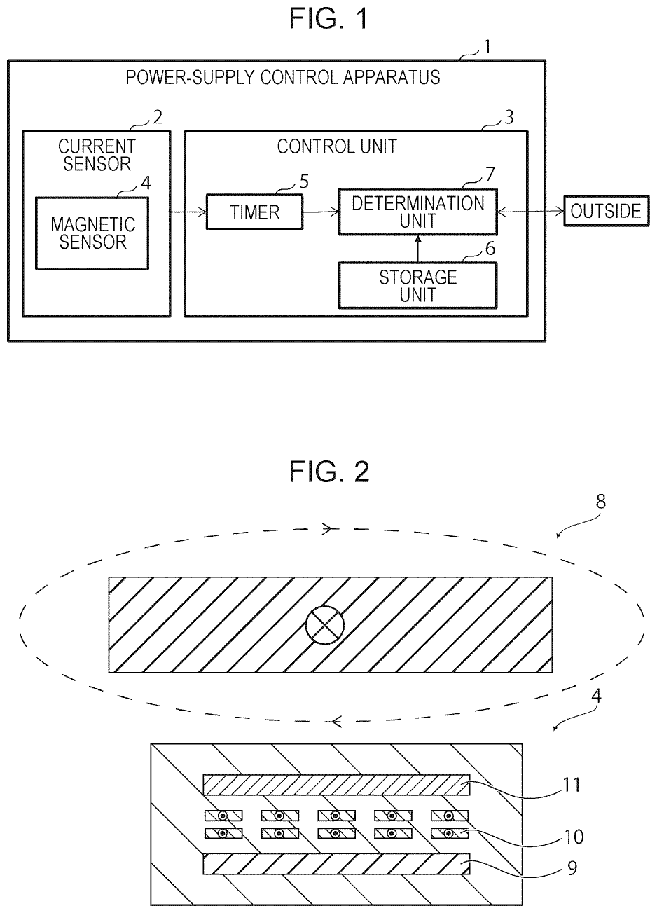

FIG. 1 is a functional block diagram illustrating a configuration of a power-supply control apparatus 1 according to the present embodiment. As illustrated in the figure, the power-supply control apparatus 1 includes a current sensor 2 configured to measure a current to be measured flowing through a bus bar, and a control unit 3 that controls the power-supply control apparatus 1.

The current sensor 2 includes a magnetic sensor 4 and measures, using a magnetic sensor 4, magnetism that occurs when a current to be measured flows through a bus bar. The magnetic sensor 4 includes a magnetoresistive element for detecting magnetism. The control unit 3 may include a timer 5, a storage unit 6, and a determination unit 7. The determination unit 7 determines whether an overcurrent has flowed through the bus bar.

The timer 5 is used to measure a time during which a current to be measured flows through the bus bar, a time elapsed after the current sensor 2 is powered on, or the like. However, in measuring this time, the time may be acquired from a portion of the power-supply control apparatus 1 other than the control unit 3, or from a timer of a device external to the power-supply control apparatus 1.

The storage unit 6 may store a threshold serving as a criterion for an overcurrent, characteristics of the magnetic sensor 4, and the like. However, the threshold, a variation-amount threshold, and the like may be acquired from a portion of the power-supply control apparatus 1 other than the control unit 3, or from an external device, for use. In this case, the storage unit 6 acquires the thresholds from the portion other than the control unit 3 or the device external to the power-supply control apparatus 1.

The determination unit 7 measures a current increase time, which is a time required for the output voltage of the current sensor 2 to rise from 0 to a maximum value, and a current decrease time, which is a time required for the output voltage of the current sensor 2 to fall from the maximum value to 0. The determination unit 7 acquires a current increase/decrease time difference, which is the difference between the current increase time and the current decrease time, and determines whether an overcurrent has flowed through the bus bar based on the current increase/decrease time difference.

The determination unit 7 can determine, at the time of startup of the power-supply control apparatus 1, whether an overcurrent has flowed through the bus bar while the current sensor 2 was stopped. When it is determined immediately after a startup time, which is a time required from when the power-supply control apparatus 1 is powered on until the current sensor 2 starts operating, that is, immediately after startup, that an overcurrent has flowed through the bus bar, the determination unit 7 determines that the overcurrent flowed during the period from when the current sensor 2 was stopped until it started.

The term “immediately after startup” refers to a time when data for one cycle of an alternating current that is output first after the power-supply control apparatus 1 has started is acquired. For example, when the current sensor 2 is operating at a frequency of 1 Hz, one second is required to acquire data for one cycle, and therefore the time one second after the power-supply control apparatus 1 has started constitutes “immediately after startup”. The startup time of the current sensor 2 varies depending on the performance of the current sensor 2, but is very short, for example, about one millisecond. For this reason, it is not possible to determine whether an overcurrent has flowed through the bus bar at the time of startup of the power-supply control apparatus 1. However, when it is determined that an overcurrent has flowed through the bus bar immediately after startup, it can be said that there is at least a high likelihood that the overcurrent flowed during the period from when the current sensor 2 was stopped until it started. When the power-supply control apparatus 1 is mounted on a vehicle, the time required from when the ignition switch of the vehicle is pressed until the power-supply control apparatus 1 starts is typically about 30 seconds to one minute.

When an overcurrent flows through the bus bar, hysteresis occurs in the magnetic sensor 4. When the current increase/decrease time difference of the output voltage of the current sensor 2 before and after the occurrence of hysteresis is compared, the current increase/decrease time difference after the occurrence of hysteresis is larger. For this reason, the determination unit 7 can determine whether an overcurrent has flowed through the bus bar based on the current increase/decrease time difference. For example, when the acquired current increase/decrease time difference exceeds a threshold, the determination unit 7 may determine that an overcurrent has flowed through the bus bar. In this case, the determination unit 7 may obtain the value of the overcurrent that has flowed through the bus bar.

When the determination unit 7 determines that an overcurrent has flowed through the bus bar, the determination unit 7 outputs a warning to the outside. In addition to the warning, a current value may be output to the outside. Because the warning indicates that an overcurrent has occurred, it becomes possible to inspect a device in which a problem may arise due to the overcurrent and to perform maintenance, repair, or replacement as necessary. Accordingly, this improves the reliability of the power-supply control apparatus 1 and the power-supply system to be controlled.

FIG. 2 is a schematic cross-sectional view of a configuration of the magnetic sensor 4 of the current sensor 2. The magnetic sensor 4 includes a magnetoresistive element 9, a feedback coil 10, and a magnetic shield 11 and detects magnetism that is generated when a current to be measured flows through a bus bar 8. However, instead of the magnetic sensor 4 in FIG. 2, a magnetic sensor including only the magnetoresistive element 9 or a magnetic sensor including one of the feedback coil 10 and the magnetic shield 11 in addition to the magnetoresistive element 9 may also be used.

The bus bar 8 is made of copper, brass, aluminum, or the like, and a current to be measured for detection flows therethrough. When a current to be measured flows through the bus bar 8, magnetism is generated around the bus bar 8. FIG. 2 schematically illustrates, using a broken line, magnetism generated around the bus bar 8 when the current to be measured flows. The magnetic sensor 4 measures the magnetism around the bus bar 8 by means of the magnetoresistive element 9.

The magnetoresistive element 9 functions as a magnetism detection element in the magnetic sensor 4. Examples of the magnetoresistive element 9 include a giant magnetoresistive element (GMR element), an anisotropic magnetoresistive element (AMR element), and a tunnel magnetoresistive element (TMR element).

The feedback coil 10 is used for magnetic equilibrium and is provided between the magnetoresistive element 9 and the magnetic shield 11. A cancel current flows through the feedback coil 10 in a direction opposite to the current to be measured that flows through the bus bar 8. FIG. 2 illustrates a case where a current to be measured flowing through the bus bar 8 flows from the front side of the drawing toward the back side, and a cancel current of the feedback coil 10 flows from the back side of the drawing toward the front side. A cancel magnetic field, which is directed so as to offset current magnetism caused by the current to be measured, is generated by the cancel current and acts on the magnetoresistive element 9.

By increasing the cancel magnetic field, the detection voltage approaches zero, and the cancel magnetic field acting on the magnetoresistive element 9 and the current magnetism become balanced, whereby the detection voltage becomes equal to or less than a predetermined value. At this time, the current flowing through the feedback coil 10 is detected as a measurement value of the current to be measured that flows through the bus bar 8.

The magnetic shield 11 is, for example, formed by laminating a plurality of metal plate-like members having the same shape. By providing the magnetic shield 11, magnetic noise from the outside is reduced, thereby improving the measurement accuracy of the magnetic sensor 4.

As illustrated in FIG. 2, the magnetic sensor 4 is arranged such that, from the side closer to the bus bar 8, the magnetic shield 11, the feedback coil 10, and the magnetoresistive element 9 are disposed in this order. The magnetoresistive (MR) magnetic sensor 4 having such a configuration is characterized in that its hysteresis increases when an overcurrent is detected. When a current to be measured flowing through the bus bar 8 is an alternating current, the influence of hysteresis caused by an overcurrent appears as a phase difference when the overcurrent flows. For this reason, an overcurrent can be detected by using a change, from an initial state, in the phase difference in the measurement.

Examples of factors that cause hysteresis in the magnetic sensor 4 due to the influence of strong magnetism generated by an overcurrent flowing through the bus bar 8 include a change in the magnetization state of the magnetoresistive element 9 and residual magnetism in the magnetic shield 11.

Since the hysteresis of the magnetic sensor 4 is maintained even after an overcurrent has flowed through the bus bar 8, it is also possible to retrospectively detect that an overcurrent has flowed through the bus bar 8 by using the hysteresis of the magnetic sensor 4. For example, even when an overcurrent has flowed through the bus bar 8 while the operation of the current sensor 2 (see FIG. 1) was stopped, the overcurrent can be detected based on the hysteresis of the magnetic sensor 4.

For example, when the power-supply control apparatus 1 is used to control a vehicle power-supply system, maintenance work may be performed while the vehicle power-supply system is stopped and the current sensor 2 is not operating. In such maintenance work, an overcurrent may flow through the bus bar 8 due to an operational mistake.

Even when an overcurrent flows while the operation of the current sensor 2 is stopped, magnetism is generated around the bus bar 8 when the overcurrent flows through the bus bar 8. The generated magnetism affects the magnetoresistive element 9 and the magnetic shield 11 of the magnetic sensor 4, as in the case where the current sensor 2 is operating. For this reason, hysteresis occurs in the magnetic sensor 4 due to the overcurrent. Accordingly, the overcurrent that has flowed through the bus bar 8 can be retrospectively detected by using the hysteresis of the magnetic sensor 4.

When it is determined that an overcurrent has flowed through the bus bar immediately after the startup of the current sensor 2, the overcurrent is deemed to have flowed during a period in which the current sensor 2 was either stopped or starting up. In view of the time required for startup, the possibility that an event causing an overcurrent occurred while the current sensor 2 was stopped is higher than the possibility that such an event occurred at the moment of startup. Accordingly, when it is determined immediately after the startup of the current sensor 2 that an overcurrent has flowed through the bus bar 8, the current sensor 2 may output to the outside a stoppage warning indicating that an overcurrent may have flowed through the bus bar 8 while the current sensor 2 was stopped. By outputting the stoppage warning to the outside, it is possible to inform the operator that there is a possibility that an overcurrent has flowed through the bus bar 8 due to an operational mistake during maintenance work while the current sensor 2 was stopped.

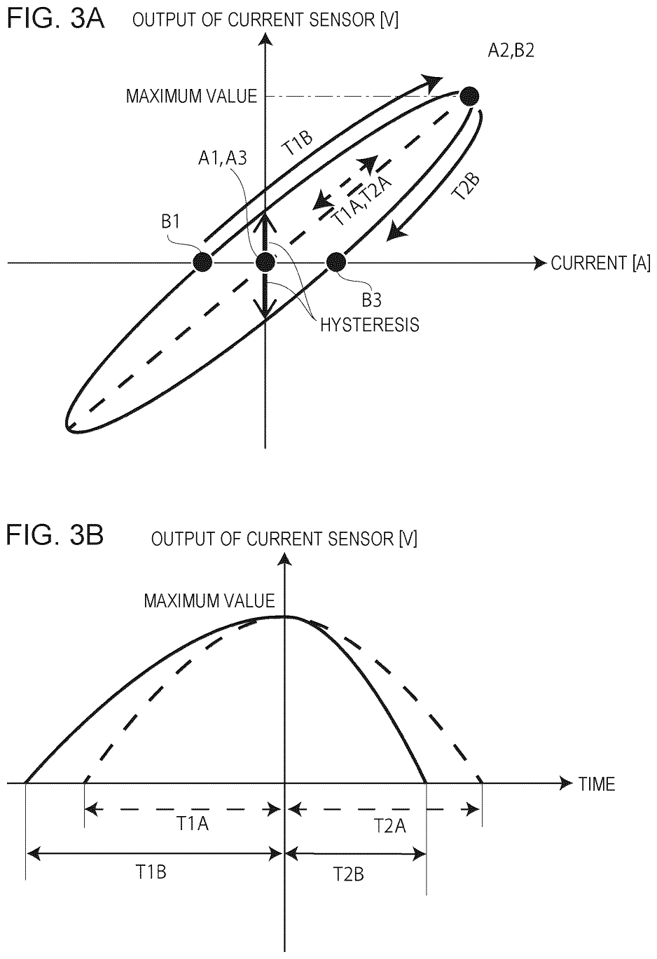

FIG. 3A is a graph showing a relationship between a primary current detected by the current sensor 2 and a voltage output from the current sensor 2 when an alternating current is measured as a current to be measured flowing through the bus bar 8. The value of the primary current detected by the current sensor 2 illustrated in FIG. 2 is obtained as the value of a current flowing through the feedback coil 10 of the magnetic sensor 4.

FIG. 3B is a graph showing changes over time in the voltage output from the current sensor 2 in FIG. 3A.

In FIGS. 3A and 3B, an initial state before an overcurrent flows through the bus bar 8 is indicated by a broken line, and a state after the overcurrent has flowed is indicated by a solid line. An ideal state is illustrated as the state before an overcurrent flows, in order to make it easy to understand the difference in the magnetic sensor 4 before and after the overcurrent flows.

As indicated by the broken line in FIG. 3A, before an overcurrent flows through the bus bar 8, the magnitude of the output is determined by the magnitude of the current. In other words, the voltage output from the current sensor 2 at the same current value is the same both in a period from when the output of the current sensor 2 rises from 0 to a maximum value and in a period until the output of the current sensor 2 falls from the maximum value back to 0. For this reason, in the graph indicated by the broken line in FIG. 3A, the locus from point A1 to point A2 and the locus from point A2 to point A3 are the same. Accordingly, a current increase time T1A required for the output to rise from 0 to a maximum value and a current decrease time T2A required for the output to fall from the maximum value back to 0 are equal.

In contrast, as indicated by the solid line in FIG. 3A, the magnitude of the output from the current sensor 2 after an overcurrent has flowed through the bus bar 8 is not determined solely by the magnitude of the current value but differs depending on a direction in which the current value changes. In other words, even when the current flowing through the bus bar 8 is the same, the magnitude of the voltage output from the current sensor 2 differs depending on whether the direction in which the output changes is an increasing direction or a decreasing direction. For this reason, in the graph indicated by the solid line in FIG. 3A, the locus from point B1 to point B2 when the voltage increases and the locus from point B2 to point B3 when the current decreases differ. Accordingly, a current increase time T1B required for the output to rise from 0 to a maximum value and a current decrease time T2B required for the output to fall from the maximum value to 0 differ, and the current increase time T1B is longer than current decrease time T2B.

As described above, when hysteresis occurs in the magnetic sensor 4, a zero-cross error occurs in the output from the current sensor 2. As a result, a difference is generated between the current increase time T1B and the current decrease time T2B. Here, the term “zero-cross error” refers to a condition in which, when the current value is 0 A, the output from the current sensor 2 differs depending on the direction in which the current value changes.

The determination unit 7 obtains the current increase time T1B and the current decrease time T2B and evaluates the magnitude of the hysteresis of the magnetic sensor 4 using a current increase/decrease time difference, which is a difference between the current increase time T1B and the current decrease time T2B, thereby detecting an overcurrent. In other words, when the current increase/decrease time difference exceeds a threshold, the determination unit 7 determines that an overcurrent has flowed through the bus bar 8.

The magnetic sensor 4 including the magnetoresistive element 9 is characterized in that, when an overcurrent occurs in the bus bar 8, its hysteresis increases. For this reason, when the current to be measured is an alternating current, the influence of an increase in hysteresis appears as a phase difference. Accordingly, by measuring a change in the phase difference from an initial value, it is possible to detect that an overcurrent has flowed through the bus bar 8 as the current to be measured.

When an overcurrent flows through the bus bar 8, hysteresis occurs in the magnetic sensor 4 regardless of whether the current sensor 2 is operating. This can be regarded as meaning that the magnetic sensor 4 stores, as hysteresis, the fact that an overcurrent has flowed through the bus bar 8. For this reason, the power-supply control apparatus 1 can extract, by obtaining the current increase/decrease time difference, a history of the influence of the overcurrent stored in the magnetic sensor 4. In other words, by measuring the current increase/decrease time difference that changes due to the hysteresis of the magnetic sensor 4 and comparing the current increase/decrease time difference with a threshold, it is possible to detect that an overcurrent has occurred even after the overcurrent has flowed. The threshold used for detecting an overcurrent is determined in view of the current increase/decrease time difference that occurs in the magnetic sensor 4 when an overcurrent flows through the bus bar 8.

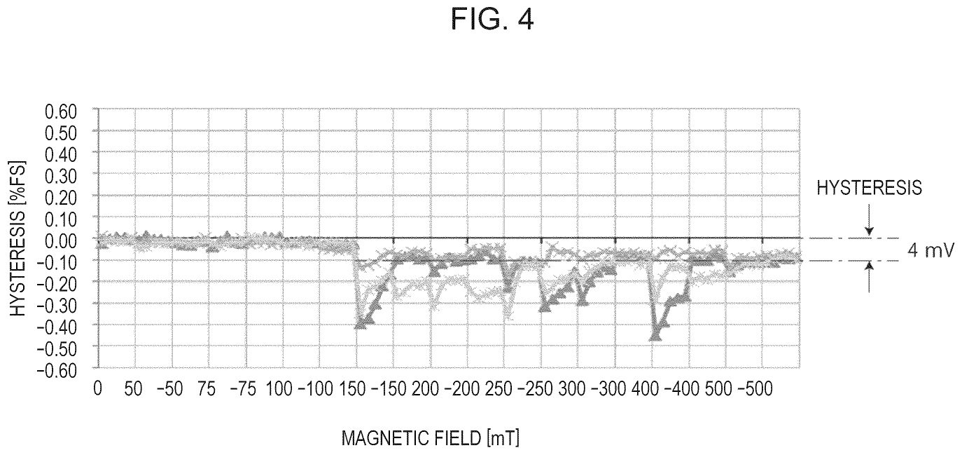

FIG. 4 is a graph showing hysteresis that occurs in the magnetic sensor 4 when strong magnetism is applied, and illustrates the influence on the magnetic sensor 4 of magnetism generated when an overcurrent flows through the bus bar 8. Specifically, the graph shows results obtained by gradually increasing the strength of magnetism applied to the magnetic sensor 4 and measuring the hysteresis of the magnetic sensor 4 after the magnetism has been applied.

As shown in the figure, when an overcurrent flows as the current to be measured of the bus bar 8 and strong magnetism of 150 mT or more is applied, hysteresis occurs in the magnetic sensor 4. The hysteresis of the magnetic sensor 4 that has occurred due to strong magnetism of 150 mT does not change even when stronger magnetism is further applied.

For example, when the hysteresis is 4 mV and the maximum value of the output from the current sensor 2 operating at 10 Hz is 2,000 mV, a time variation (T2A-T2B in FIG. 3B) in a quarter sine wave obtained by dividing a sine wave into four portions (B2 to B3 in FIG. 3A) is obtained by the following equation:

$$1 s / 10 / 360 ° \times ( 90 ° / 2 , 000 mV \times 4 mV ) = 50 μs$$

The peak of the quarter sine wave corresponding to an output of 90° is 2,000 mV, whereas, as illustrated in FIG. 3A, at a current value of 0 A, a displacement corresponding to the entire sine wave—namely, a full-scale displacement—from the initial state occurs. For this reason, the time variation can be calculated by using the hysteresis value of 4 mV and the peak value of the quarter sine wave of 2,000 mV in the above equation.

When an alternating current is measured by the current sensor 2, the magnitude of a time variation caused by the hysteresis of the magnetic sensor 4 depends on the frequency. The relationship between the frequency and a time variation in the quarter sine wave when the maximum value of the output from the current sensor is 2,000 mV and the hysteresis is 4 mV is shown in the following table.

TABLE 1

| Frequency [Hz] | Time Variation [μs] |
|---|---|
| 1 | 500 |
| 10 | 50 |
| 100 | 5 |
| 1,000 | 0.5 |

In the above example, when the current sensor 2 is operating at 10 Hz, the variation time of the current increase time T1B is +50 μs, and the time variation of the current decrease time T2B is −50 μs. Accordingly, a threshold used to detect that an overcurrent has flowed through the bus bar 8 as a current to be measured is obtained by the following equation:

$$T 1 B - T 2 B = ( T 1 A + 50 μs ) - ( T 2 A - 50 μs ) = ( T 1 A - T 2 A ) + 100 μs$$

When T1A and T2A are equal as indicated by the broken lines in FIGS. 3A and 3B, the threshold is 100 μs. In this manner, the threshold determined based on the current increase/decrease time difference T1B-T2B that occurs in the magnetic sensor 4 when an overcurrent flows through the bus bar 8 can be used for detecting an overcurrent.

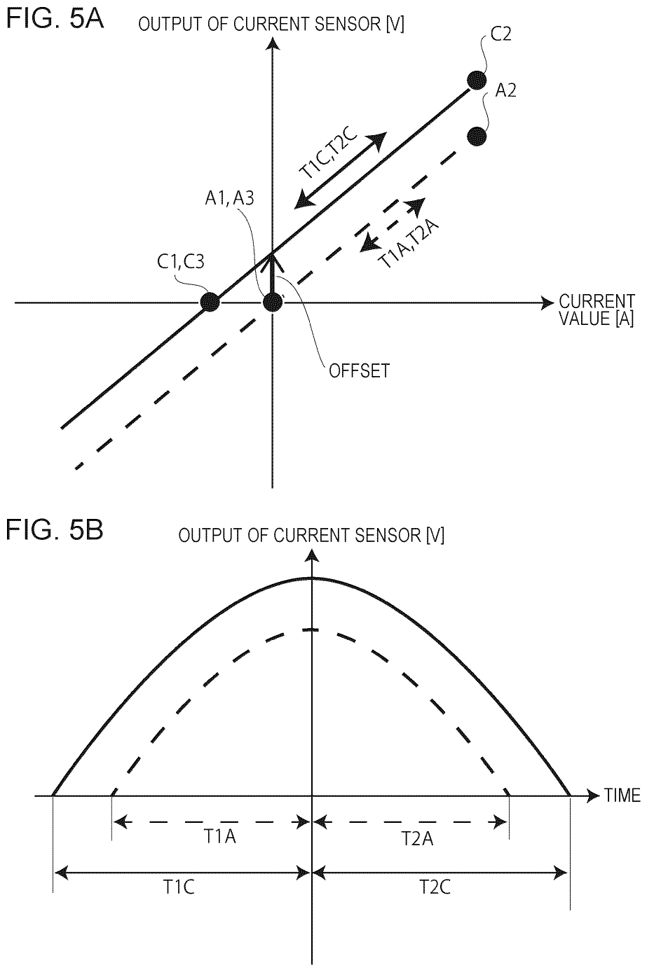

FIG. 5A is a graph showing the relationship between a primary current detected by the current sensor 2 and a voltage output from the current sensor 2 when an alternating current flowing through the bus bar 8 is measured as the current to be measured. In the figure, a state before an offset occurs is indicated by the broken line, and a state after the offset occurs is indicated by the solid line.

FIG. 5B is a graph showing the relationship between time and a voltage output from the current sensor 2 before and after an offset occurs in the magnetic sensor 4 included in the current sensor 2. In the figure, a state before an offset occurs in the magnetic sensor 4 is indicated by the broken line, and a state after the offset occurs is indicated by the solid line. The state before the offset occurs in FIGS. 5A and 5B is the same as the state before the overcurrent occurs in FIGS. 3A and 3B.

As shown in FIG. 5A, an offset may occur in the magnetic sensor 4 due to temperature change. However, when an offset occurs in the magnetic sensor 4, both the current increase time T1C and the current decrease time T2C increase by the same amount, as illustrated in FIG. 5B. Accordingly, the current increase/decrease time difference (=T1C−T2C), which is the difference between the current increase time T1C and the current decrease time T2C, is not affected by the offset.

### <Overcurrent Detection Method>

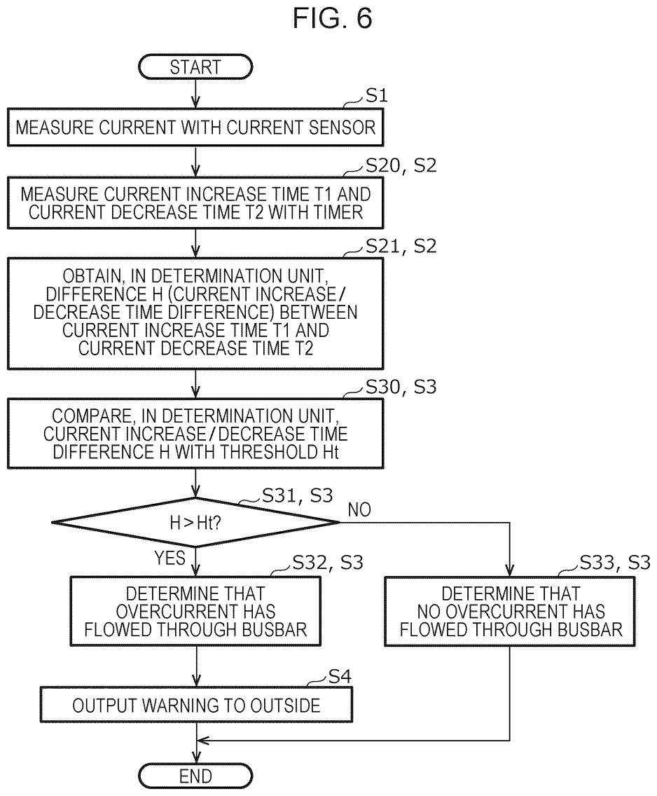

FIG. 6 is a flowchart of an overcurrent detection method according to the present embodiment. The flowchart illustrates a method for determining whether an overcurrent has flowed through the power-supply control apparatus 1. The power-supply control apparatus 1 includes the current sensor 2 capable of measuring a current to be measured. The current sensor 2 includes the magnetic sensor 4 for detecting magnetism generated when a current to be measured flows through the bus bar 8. The flowchart illustrated in the figure shows a case where a predetermined value of a current increase/decrease time difference H is used as a threshold, and when the current increase/decrease time difference H exceeds the threshold, it is determined that an overcurrent has flowed through the bus bar 8.

The overcurrent detection method includes measurement step S1, evaluation step S2, and determination step S3.

In the measurement step S1, a current to be measured flowing through the bus bar 8 is measured by the current sensor 2. In the evaluation step S2, the control unit 3 obtains the hysteresis of the magnetic sensor 4 based on the measurement result of the measurement step S1. In the determination step S3, when the hysteresis exceeds the threshold, the determination unit 7 determines that an overcurrent has flowed through the bus bar 8.

The evaluation step S2 of evaluating the hysteresis includes step S20 of obtaining a current increase time T1 and a current decrease time T2 and step S21 of obtaining the current increase/decrease time difference H.

In step S20, the current increase time T1, which is a time required for the output voltage of the current sensor 2 to rise from 0 to a maximum value, and the current decrease time T2, which is a time required for the output voltage of the current sensor 2 to fall from the maximum value to 0, are obtained by using the timer 5.

In step S21, the current increase/decrease time difference H, which is the difference between the current increase time T1 and the current decrease time T2, is obtained by the determination unit 7.

The determination step S3 includes S30 to S33. In step S30, the current increase/decrease time difference H and a threshold Ht are compared by the determination unit 7. If the current increase/decrease time difference H is greater than the threshold Ht (H>Ht, Yes in S31), then in S32 it is determined that an overcurrent has flowed through the bus bar 8. In this case, the process moves to output step S4, and the control unit 3 may output a warning to the outside of the power-supply control apparatus 1 and ends the measurement of the overcurrent. If the current increase/decrease time difference H is equal to or less than the threshold Ht (H≤Ht, No in S31), then in S33 it is determined that no overcurrent is flowing through the bus bar 8, and the overcurrent determination is completed.

### <Modification 1>

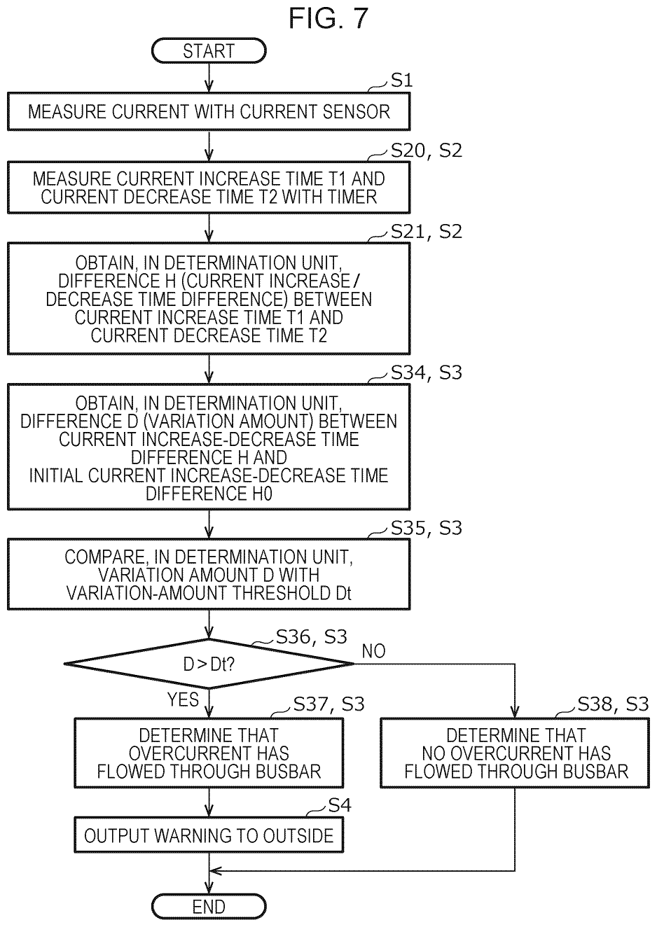

FIG. 7 is a flowchart of an overcurrent detection method according to Modification 1, and illustrates a detection method in which hysteresis of the current sensor 2 at the time of measurement is compared with initial hysteresis, and when a variation amount with respect to the initial hysteresis is equal to or greater than a threshold, it is determined that overcurrent has flowed.

The overcurrent detection method shown in the figure differs from the overcurrent detection method shown in FIG. 6 in that, instead of the current increase/decrease time difference H, a variation amount D with respect to an initial value H0 is used. In other words, in the overcurrent detection method according to the modification, the determination unit 7 obtains the variation amount D with respect to the initial value H0 of the current increase/decrease time difference H, and when the variation amount D exceeds a variation-amount threshold Dt, the determination unit 7 determines that an overcurrent has flowed through the bus bar 8.

Description of portions identical to the flowchart shown in FIG. 6 is omitted, and the following description focuses on different portions. Determination step S3 in the modification includes S34 to S38. In S34, a variation amount D, which is the difference between the current increase/decrease time difference H and the initial value H0, is obtained by the determination unit 7. In S35, the variation amount D and the variation-amount threshold Dt are compared by the determination unit 7. The initial value H0 is a characteristic of the magnetic sensor 4 and is stored in the storage unit 6 (see FIG. 1).

If the variation amount D is greater than the variation-amount threshold Dt (D≥Dt, Yes in S36), then in S37 it is determined that an overcurrent has flowed through the bus bar 8. In S4, a warning is output to the outside, and the overcurrent determination is completed. If the variation amount D is equal to or less than the variation-amount threshold Dt (D≤Dt, No in S36), then in S38 it is determined that no overcurrent is flowing through the bus bar 8, and the overcurrent determination is completed.

The initial value H0 of the initial current increase/decrease time difference H varies depending on the individual variations of the magnetic sensor 4. Accordingly, in the modification, instead of obtaining the current increase/decrease time difference H and comparing it with the threshold Ht in the determination step S3, the variation amount D from the initial value H0 of the current increase/decrease time difference H is obtained, and compared with the variation-amount threshold Dt. Since the influence of individual variations of the current sensor 2 is eliminated by obtaining the variation amount D, the accuracy of detecting that an overcurrent has flowed through the bus bar 8 is improved.

### <Modification 2>

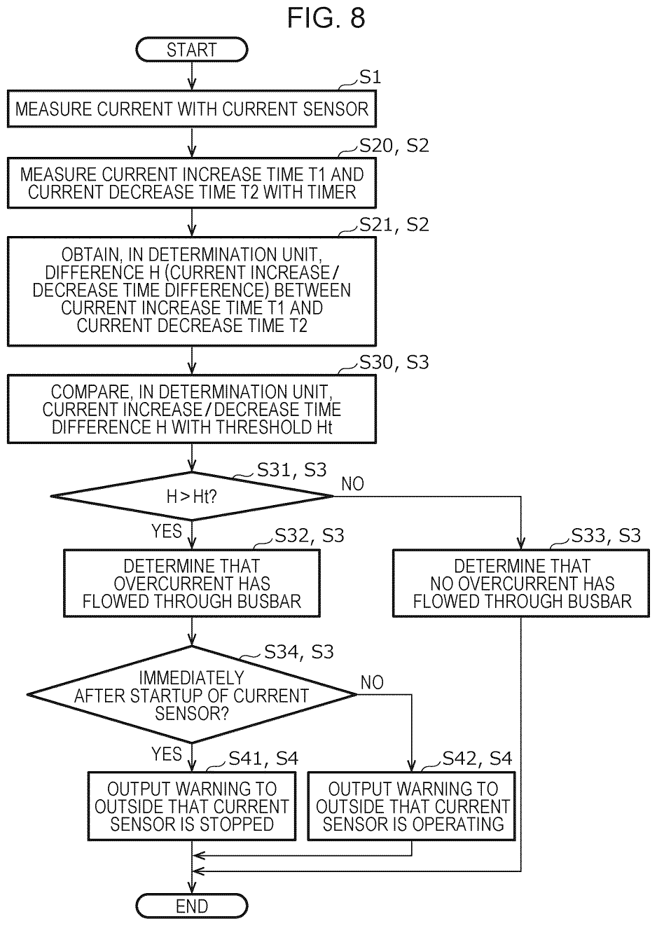

FIG. 8 is a flowchart of an overcurrent detection method according to Modification 2. When driving of a vehicle has ended and a power source such as an engine or a motor is stopped, the current sensor 2 also stops, and essentially no electric current flows through the bus bar 8. However, as described above, when the power source is stopped for maintenance and inspection of the vehicle, there is a possibility that an overcurrent may flow due to an operator's mistake. In the example shown in the figure, when it is determined immediately after the startup of the current sensor 2 that an overcurrent has flowed through the current sensor 2, a stoppage warning indicating that an overcurrent may have flowed through the bus bar 8 while the current sensor 2 was stopped is output to the outside. When it is determined at a timing later than immediately after the startup of the current sensor 2 that an overcurrent has flowed through the current sensor 2, a warning indicating that an overcurrent has flowed through the bus bar 8 while the current sensor 2 was operating is output to the outside.

Description of portions identical to the flowchart shown in FIG. 6 is omitted, and the following description focuses on different portions. Determination step S3 in Modification 2 includes S31 to S34. In S34, the determination unit 7 determines whether it is determined immediately after the startup of the current sensor 2 that an overcurrent has flowed through the bus bar 8. The predetermined time is a characteristic of the current sensor 2 and is stored in the storage unit 6 (see FIG. 1).

If it is determined immediately after the startup of the current sensor 2 that an overcurrent has flowed through the bus bar 8 (Yes in S34), it is determined that there is a high likelihood that an overcurrent may have flowed through the bus bar 8 while the current sensor 2 was stopped. In S41, a stoppage warning indicating that the power sensor stops is output to the outside, and the overcurrent determination is completed. For example, a current increase/decrease time difference at the output voltage of the current sensor 2 immediately after startup is obtained, and when the current increase/decrease time difference exceeds a threshold, it can be determined that an overcurrent has flowed while the current sensor 2 was stopped or started. Alternatively, a variation amount of the output voltage of the current sensor 2 immediately after startup may be obtained, and when the variation amount exceeds a variation-amount threshold, it may be determined that an overcurrent flowed while the current sensor 2 was stopped or started. If it is determined at a timing later than immediately after the startup of the current sensor 2 that an overcurrent has flowed through the bus bar 8 (No in S34), it is determined that an overcurrent has flowed through the bus bar 8 while the current sensor 2 was operating, and in S42, a warning indicating that the power sensor is operating is output to the outside, and the overcurrent determination is completed.

In the overcurrent detection method shown in FIG. 8, different warnings are output to the outside depending on whether, in step S32, it is determined that an overcurrent has flowed through the bus bar 8 immediately after the startup of the current sensor 2 or at a timing later than the immediately after the startup. This enables the operator to determine whether an overcurrent flowed through the bus bar 8 while the current sensor 2 was stopped or while it was operating, and therefore to take more appropriate measures according to the presumed cause.

Although FIG. 8 illustrates an embodiment in which steps S34, S41 and S42 are performed after step S32 in FIG. 6, steps S34, S41, and S42 may be performed after step S37 in FIG. 7.

The embodiments disclosed in the present specification are merely illustrative in all respects and are not intended to be limiting. The scope of the present invention is not limited to the above-described embodiments, but is defined by the claims, and is intended to include all modifications within the meaning and scope equivalent to the claims.

### INDUSTRIAL APPLICABILITY

The present invention is useful, for example, as a power-supply control apparatus that measures a current to be measured flowing through various devices and controls a vehicle power-supply system or the like.

What is claimed is:

1. A power-supply control apparatus comprising:
a current sensor including a magnetic sensor that detects, using a magnetoresistive element, magnetism generated when a current to be measured flows through a bus bar, the current sensor being capable of measuring the current to be measured; and
a determination unit that determines whether an overcurrent has flowed through the bus bar,
wherein the determination unit measures a current increase time, the current increase time being a time required for an output voltage of the current sensor to rise from 0 to a maximum value, and a current decrease time, the current decrease time being a time required for the output voltage of the current sensor to fall from the maximum value to 0, obtains a current increase/decrease time difference that is a difference between the current increase time and the current decrease time, and determines whether the overcurrent has flowed through the bus bar based on the current increase/decrease time difference.

2. The power-supply control apparatus according to claim 1, wherein, when the determination unit determines that the overcurrent has flowed through the bus bar, the determination unit outputs a warning to the outside.

3. The power-supply control apparatus according to claim 1, further comprising:
a storage unit that stores a threshold of the current increase/decrease time difference, the threshold serving as a reference for the determination unit to determine whether a current that has flowed through the bus bar is the overcurrent,
wherein when the obtained current increase/decrease time difference has exceeded the threshold, the determination unit determines that the overcurrent has flowed through the bus bar.

4. The power-supply control apparatus according to claim 1, further comprising:
a storage unit that stores a variation-amount threshold of the current increase/decrease time difference, the variation-amount threshold serving as a reference for the determination unit to determine whether a current that has flowed through the bus bar is the overcurrent, and an initial value of the current increase/decrease time difference,
wherein the determination unit obtains a variation amount of the current increase/decrease time difference, the variation amount being a difference between the obtained current increase/decrease time difference and the initial value of the current increase/decrease time difference, and determines that the overcurrent has flowed through the bus bar when the obtained variation amount exceeds the variation-amount threshold.

5. An overcurrent detection method comprising:
measuring a current to be measured that flows through a bus bar using a current sensor including a magnetic sensor that detects, using a magnetoresistive element, magnetism generated when the current to be measured flows through a bus bar, the current sensor being capable of measuring the current to be measured;
measuring a current increase time, the current increase time being a time required for an output voltage of the current sensor to rise from 0 to a maximum value, and a current decrease time, the current decrease time being a time required for the output voltage of the current sensor to fall from the maximum value to 0;
obtaining a current increase/decrease time difference that is a difference between the current increase time and the current decrease time; and
determining whether an overcurrent has flowed through the bus bar based on the current increase/decrease time difference.

6. The overcurrent detection method according to claim 5, wherein, when the obtained current increase/decrease time difference exceeds a threshold, it is determined that the overcurrent has flowed through the bus bar.

7. The overcurrent detection method according to claim 5, wherein a variation amount of the current increase/decrease time difference is obtained, the variation amount being a difference between the obtained current increase/decrease time difference and the initial value of the current increase/decrease time difference, and it is determined that the overcurrent has flowed through the bus bar when the obtained variation amount exceeds the variation-amount threshold.

8. The overcurrent detection method according to claim 6,
wherein the current increase/decrease time difference at the output voltage of the current sensor immediately after startup or the variation amount is obtained, and when the current increase/decrease time difference exceeds the threshold, or when the variation amount exceeds the variation-amount threshold, a warning indicating a high likelihood that the overcurrent flowed through the bus bar while the current sensor was stopped is output.
